(19) United States
(12) Patent Application Publication
(10) Pub. No.: US 2017/0373263 A1
(43) Pub. Date: Dec. 28, 2017

(54) Organic/Inorganic Hybrid Electroluminescent Device with Two-Dimensional Material Emitting Layer

(71) Applicant: Nanoco Technologies Ltd., Manchester (GB)

(72) Inventors: Stuart Stubbs, Manchester (GB); Stephen Whitelegg, Manchester (GB); Nigel Pickett, Manchester (GB); Zugang Liu, Manchester (GB)

(21) Appl. No.: 15/625,310

(22) Filed: Jun. 16, 2017

Related U.S. Application Data
(60) Provisional application No. 62/355,591, filed on Jun. 28, 2016.

(51) Int. Cl. H01L 51/50; H01L 51/56; H01L 51/52; H01L 51/00

(52) U.S. Cl. CPC H01L 51/502; H01L 51/5096; H01L 51/0097; H01L 51/56; H01L 51/5237; H01L 51/5221; H01L 51/5206; H01L 51/0003; H01L 51/5092; H01L 51/5088; H01L 51/5072; H01L 51/5056; H01L 2251/5338; H01L 2251/5353

(57) ABSTRACT

An organic light-emitting diode with an inorganic two-dimensional (2D) EL active material may comprise a plurality of layers on a plastic or glass substrate. In addition to the EL layer, the device may comprise a hole injection layer, a hole transport layer/electron blocking layer, an electron transport layer/hole blocking layer, an electron injection layer, and optional buffer layers such as poly(methyl methacrylate) (PMMA) to help balance the charge injection into the 2D material and redistribute the electric field.

### CROSS-REFERENCE TO RELATED APPLICATIONS

This application is a non-provisional of U.S. Provisional Application Ser. No. 62/355,591, filed Jun. 28, 2016, the entire contents of which are incorporated herein by reference.

### STATEMENT REGARDING FEDERALLY SPONSORED RESEARCH OR DEVELOPMENT

Not Applicable

### BACKGROUND OF THE INVENTION

### 1. Field of the Invention

The present invention generally relates to electroluminescent (EL) devices. More particularly, it relates organic/inorganic hybrid EL devices.

### 2. Description of the Related Art Including Information Disclosed Under 37 CFR 1.97 and 1.98

Two-dimensional (2D) nanosheets of transition metal dichalcogenide (TMDC) materials are of increasing interest for applications ranging from catalysis to sensing, energy storage and optoelectronic devices, due to their unique optical and electronic properties.

Mono- and few-layer TMDCs have been shown to exhibit direct bandgap semiconductor behaviors, with variation in band gap and carrier type (n- or p-type) depending on composition, structure and dimensionality, whereas multilayer TMDCs exhibit indirect bandgap semiconductor properties. The offset of the valance and conduction bands has been calculated and shown to be a function of the number of layers. [J. Kang, S. Tongay, J. Shou, J. Li and J. Wu, Appl. Phys. Lett., 2013, 102, 012111/1]

Of the 2D TMDCs, the semiconductors WSe₂ and MoS₂ are of particular interest because, while largely preserving their bulk properties, additional properties arise due to quantum confinement effects when the dimensions of the materials are reduced to mono- or few layers. In the case of WSe₂ and MoS₂, these include the exhibition of an indirect to direct band gap transition, with strong excitonic effects, when the thickness is reduced to a single or a few monolayers. This leads to strong enhancement in the photoluminescence (PL) efficiency, opening up new opportunities for their application in optoelectronic devices. Other materials of interest include WS₂ and MoSe₂.

Group 4 to 7 TMDCs predominantly crystallise in layered structures, leading to anisotropy in their electrical, chemical, mechanical and thermal properties. Each layer comprises a hexagonally packed layer of metal atoms sandwiched between two layers of chalcogen atoms via covalent bonds. Neighboring layers are weakly bound by van der Waals interactions, which may easily be broken by mechanical or chemical methods to create mono- and few-layer structures.

Other classes of 2D materials of interest for semiconductor applications include binary compounds of Group 14 elements, and Group 13-15 (III-V) compounds.

Recently, it has been shown that under the influence of an electric field, multilayer TMDC EL emission paths can be changed from indirect to direct bandgap emission in an all-inorganic device. [D. Li, R. Cheng, H. Zhou, C. Wang, A. Yin, Y. Chen, N. O. Weiss, Y. Huang and X. Duan, Nat. Commun., 2015, 6, 7509] In this example, the EL intensity was maintained from 1 to 50 layers of MoS₂.

Using an acid etch process, near-unity PL efficiency has been demonstrated in MoS₂ 2D materials [M. Amani, D.-H. Lien, D. Kiriya, J. Xiao, A. Azcatl, J. Noh, S. R. Madhvapathy, R. Addou, S. KC, M. Dubey, K. Cho, R. M. Wallace, S.-C. Lee, J.-H. He, J. W. Ager III, X. Zhang, E. Yablonovitch and A. Javey, Science, 2015, 350, 1065]. This demonstrates the potential for achieving highly efficient EL devices.

A buffer layer can be used to optimize the balance of charge injection of holes and electrons into the light-emitting material and redistribute the electric field within the stack.

Band offset calculations for a range of 2D materials have been calculated by Kang et al. [J. Kang, S. Tongay, J. Shou, J. Li and J. Wu, Appl. Phys. Lett., 2013, 102, 012111/1]

Inorganic-based EL devices have been demonstrated by Kretinin et al. [A. V. Kretinin, Y. Cao, J. S. Tu, G. L. Yu, R. Jalil, K. S. Novoselov, S. J. Haigh, A. Gholinia, A. Mishchenko, M. Lozada, T. Georgiou, C. R. Woods, F. Withers, P. Blake, G. Eda, A. Wirsig, C. Hucho, K. Watanabe, T. Tanaguchi, A. K. Geim and R. V. Gorbachev, Nano Lett., 2014, 14, 3270]. It was shown that the EL intensity level may be maintained in a multilayer MS₂ emitter (M=Mo; W).

In recent years, organic light-emitting diodes (OLEDs) have been of great interest within the display industry. It is thought that the solution processability of OLED devices may lead to a low production cost once mass production has been fully established, and can enable the fabrication of devices on flexible substrates, leading to new technologies such as roll-up displays. In an OLED device, the pixels emit directly, enabling a greater contrast ratio and wider viewing angle compared to liquid crystal displays (LCDs). Further, in contrast to LCDs, OLED displays do not require a backlight, allowing a true black when the OLED is switched off. OLEDs also offer faster response times than LCDs. However, OLED devices typically suffer from poor stability and lifetimes, owing to the lifespans of the organic emissive materials. Blue OLEDs currently display much lower external quantum efficiencies than green and red OLEDs. Further, OLEDs often suffer from broad emission; for display applications narrower emission is desirable to provide better colour purity.

Thus, there is a need for a solution-processable emissive device with good stability and lifetime and improved blue emission.

### BRIEF SUMMARY OF THE INVENTION

A 2D-OLED hybrid device with an inorganic 2D EL active material may comprise a plurality of layers on a plastic or glass substrate. In addition to the EL layer, the device may comprise a hole injection layer, a hole transport layer/electron blocking layer, an electron transport layer/hole blocking layer, an electron injection layer, and optional buffer layers such as poly(methyl methacrylate) (PMMA) to help balance the charge injection into the 2D material and redistribute the electric field.

Solvent-based solution coating and/or thermal processing may be used to build the device structure.

### BRIEF DESCRIPTION OF THE SEVERAL VIEWS OF THE DRAWING(S)

FIG. 1 is a schematic representation of an EL device according to an embodiment of the invention.

FIG. 2 is a schematic representation of an EL device with an inverted structure according to an embodiment of the invention.

FIG. 3 is an energy band diagram of an exemplary organic-based LED structure with an inorganic monolayer of MoSe₂ acting as the emission center.

### DETAILED DESCRIPTION OF THE INVENTION

A “2D-OLED hybrid device” refers to a multi-layer, light-emitting device having one or more organic layers and an electroluminescent (EL) active layer that comprises a 2D material. As used herein, “hybrid” means comprising at least two different types of materials. In certain embodiments, a 2D-OLED device according to the invention comprises an inorganic 2D material and a plurality of organic components. Yet other embodiments of the invention include additional inorganic components. “Hybrid” may also refer to the presence of both 2D and non-2D material in a device. Non-2D material may be bulk material or other types of nanoparticles such as conventional quantum dots.

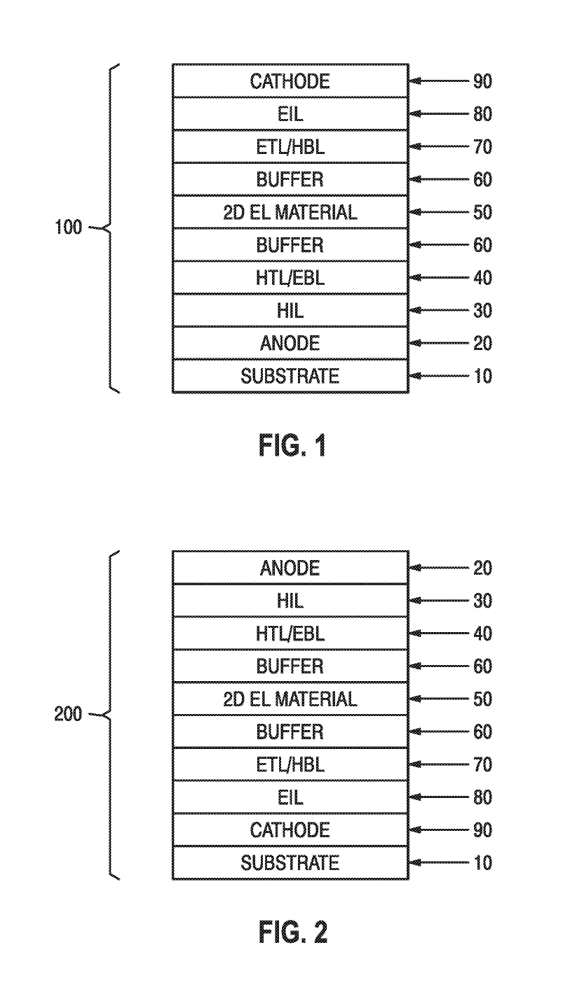

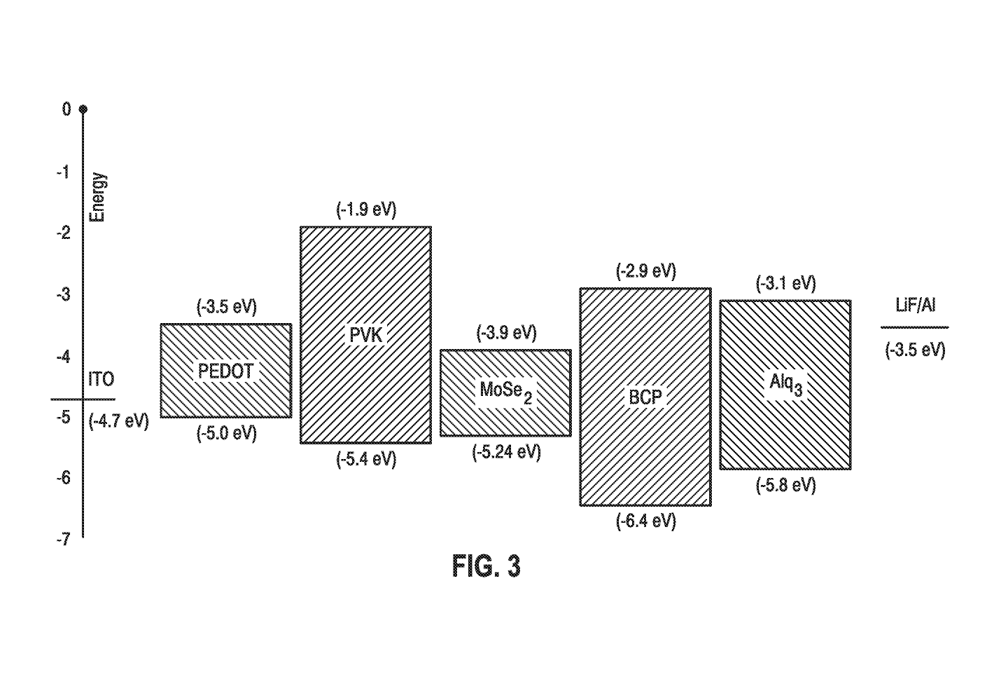

A 2D-OLED hybrid device with an inorganic 2D EL active material may comprise some or all of the layers depicted in FIG. 1, which shows a conventional device stack (100). As used herein “conventional device stack” and “conventional device structure” refer to a device wherein the anode is adjacent to the substrate. In an alternative embodiment, a 2D-OLED hybrid device with a 2D EL active layer may comprise an inverted device stack (200), as depicted in FIG. 2. As used herein “inverted device stack” and “inverted device structure” refer to a device wherein the cathode is adjacent to the substrate.

The material may be processed on a suitable substrate (10), such as a plastic or glass substrate, and can include both rigid and flexible substrates. Suitable plastic substrates include, but are not restricted to: polyethylene terephthalate (PET); polyethylene naphthalate (PEN); polycarbonate (PC); polyestersulfone (PES); polyacrylates (PAR); polycyclic olefin (PCO); and polyimide (PI).

In a conventional device stack (100) an anode material (20) may be deposited on the substrate. In an inverted device stack (200) a cathode material (90) may be deposited on the substrate. In a conventional device stack, suitable anode materials may include, but are not restricted to, transparent conducting oxides, such as indium tin oxide (ITO), aluminum-doped zinc oxide (AZO), gallium-doped zinc oxide (GZO), zirconium-doped zinc oxide (ZZO), fluorine-doped tin oxide (FTO), and including alloys and doped derivatives thereof. In an inverted device stack, the aforementioned materials would act as a cathode.

A hole injection layer (HIL; 30) may comprise a material such as, but not restricted to: molybdenum trioxide (MoO₃); 1,4,5,8,9,11-hexaazatriphenylenehexacarbonitrile (HAT-CN); or a conducting polymer such as, for example, poly(3,4-ethylene dioxythiophene) (PEDOT) or poly(3,4-ethylene dioxythiophene):poly(styrene sulfonate) (PEDOT:PSS).

A hole transport layer/electron blocking layer (HTL/EBL; 40) may include, but is not restricted to, poly-(N-vinyl carbazole) (PVK), poly(4-butylphenyl-diphenyl-amine) (poly-TPD), poly(9,9-dioctylfluorene-alt-N-(4-sec-butylphenyl)diphenylamine) (TFB), tris(4-carbozoyl-9-ylphenyl)amine (TCTA), and N,N′-di(1-naphthyl)-N,N′-diphenyl-(1,1′-biphenyl)-4,4′-diamine (NPB).

Buffer layer(s) (60) may be used to help balance the charge injection into the 2D material and redistribute the electric field. Suitable buffer layer materials include, but are not restricted to, poly(methyl methacrylate) (PMMA), aluminium oxide, poly(ethylenimine) ethoxylated, poly(9-vinylcarbazole) (PVK), cesium carbonate (Cs₂CO₃), and polyvinylpyrrolidone.

The 2D EL active layer (50) may comprise one or more 2D materials capable of exciton generation. In one embodiment, the thickness of the 2D EL active layer is between 1-5 monolayers. For example, it may be desirable to employ a 2D EL active layer having a thickness of a single monolayer to preserve the 2D character of the material and/or to avoid stacking. Suitable materials include 2D semiconductor materials such as, but not restricted to:

transition metal dichalcogenides (TMDCs) such as, for example, WO₂; WS₂; WSe₂; WTe₂; MoO₂; MoS₂; MoSe₂; MoTe₂; ScO₂; ScS₂; ScSe₂; CrO₂; CrS₂; CrSe₂; CrTe₂; NiO₂; NiS₂; NiSe₂; NbS₂; NbSe₂; PtS₂; PtSe₂; ReSe₂; HfS₂; HfSe₂; TaS₂; TaSe₂; TiS₂; TiSe₂; ZrS₂; ZrSe₂; VO₂; VS₂; VSe₂; and VTe₂;

transition metal trichalcogenides such as, for example, ZrS₃; ZrSe₃; HfS₃; and HfSe₃;

Group 13-15 (III-V) compounds such as, for example, AlN; GaN; InN; InP; InAs; InSb; GaAs; BP; BAs; GaP; AlSb; and BSb;

Group 13-16 (III-VI) compounds such as, for example, GaS, GaSe; Ga₂S₃; Ga₂Se₃; InS; InSe; In₂S₃; and In₂Se₃;

Group 14-16 (IV-VI) compounds such as, for example, Sn₅₂; SnSe₂; SnO; SnS; SnSe; GeS; GeS₂; and GeSe;

Group 15-16 (V-VI) compounds such as, for example, Sb₂S₃; Sb₂Se₃; Sb₂Te₃; Bi₂S₃; and Bi₂Se₃;

ternary metal chalcogenides such as, for example, MnIn₂Se₄; MgIn₂Se₄; ZnIn₂S₄; Pb₂Bi₂Se₅; SnPSe₃; CdPSe₃; Cu₃PS₄; and PdPSe;

binary compounds of Group 14 (IV) elements such as, for example, SiC; GeC; SnGe; SiGe; SnSi; and SnC; and

including alloys and doped derivatives thereof.

An electron transport layer/hole blocking layer (ETL/HBL; 70) may include, but is not restricted to, bathocuproine (BCP), zinc oxide nanoparticles, tris(8-hydroxyquinolinato)aluminium (Alq₃), and 2,2′,2″-(1,3,5-benzinetriyl)-tris(1-phenyl-1-H-benzimidazole) (TPBi).

An electron injection layer (EIL; 80) may include an organometallic chelate such as, but is not restricted to, lithium fluoride (LiF).

In a conventional device stack (100), suitable cathode (90) materials may include, but are not restricted to, aluminum. In an inverted device stack (200), the aforementioned material would act as an anode.

Solvent-based solution coating and/or thermal processing, such as chemical vapor deposition (CVD) and physical vapor deposition (PVD), including, but not restricted to, thermal evaporation and sputter coating, may be used to build the device structure.

Solution-based deposition approaches are well known in the art. Examples include, but are not restricted to: drop-casting; spin coating; slit coating; doctor blading; spray coating; slot dye coating; and inkjet printing. Advantages of solution-based deposition include high material utilization, which may lead to a low cost, high throughput process.

In one embodiment, the 2D EL active layer is deposited from 2D nanoparticles. A nanoparticle-based deposition approach offers many potential advantages. The preparation of 2D nanoparticles are described in Applicant's co-pending US patent application Ser. Nos. 62/355,428, 62/393,387, 62/453,780, 62/440,745 and 62/461,613, which are hereby incorporated by reference in their entirety. “Bottom-up” approaches to nanoparticle synthesis are particularly advantageous for their scalability, providing uniform composition, size and shape that may be tailored by manipulating the reaction conditions. The nanoparticles may be surface functionalized with organic ligands, which may impart solubility in a range of solvents. In a particular embodiment, the lateral dimensions of the nanoparticles may be in the quantum confinement regime, wherein the optical, electronic and chemical properties of the nanoparticles may be manipulated by changing their lateral dimensions. For example, metal chalcogenide monolayer nanoparticles of materials such as MoSe₂ and WSe₂ with lateral dimensions of approximately 10 nm or less may display properties such as size-tunable emission when excited by electricity. This may enable the electroluminescence maximum (ELₘₐₓ) of the device to be tuned by manipulating the lateral dimensions of the 2D nanoparticle. For example, Jin et al. reported the synthesis of WSe₂ single-layer nanoparticles displaying photoluminescence between 420 nm to 750 nm by varying the lateral dimensions of the particles between 2.5 nm and 9.7 nm. [H. Jin, M. Ahn, S. Jeong, J. H. Han, D. Yoo, D. H. Son and J. Cheon, J. Am. Chem. Soc., 2016, 138, 13253]

The nanoparticles may be functionalized with ligands during synthesis. In a further embodiment, the inherent ligands deposited on the nanoparticle surface during nanoparticle synthesis may be exchanged with alternative ligands to impart a particular function, such as improved solution processability and/or good charge injection. Ligand exchange procedures are well known in the art. In one embodiment, the nanoparticles may be surface functionalized with short-chain ligands. As used herein, a “short-chain ligand” refers to a ligand having a hydrocarbon chain of eight carbons or fewer. Examples of suitable short-chain ligands include, but are not restricted to: alkane thiols such as, for example, 1-octanethiol, 1-heptanethiol, 1-hexanethiol, 1-pentanethiol, 1-butanethiol, 1-propanethiol; and carboxylic acids such as, for example, octanoic acid, heptanoic acid, hexanoic acid, pentanoic acid, butanoic acid, and propanoic acid. Short-chain ligands may enable close packing of the nanoparticles for improved charge transport. In an alternative embodiment, the nanoparticles may be surface functionalized with entropic ligands. As used herein, “entropic ligand” refers to a ligand having an irregularly branched alkyl chain. Examples of suitable entropic ligands include, but are not restricted to: irregularly branched thiols such as, for example, 2-methylbutanethiol, and 2-ethylhexanethiol; and irregularly branched alkanoic acids such as, for example, 4-methyloctanoic acid, 4-ethyloctanoic acid, 2-butyloctanoic acid, 2-heptyldecanoic acid, and 2-hexyldecanoic acid. Entropic ligands have been found to assist in the nanoparticle processability, while retaining or improving their performance in devices. [Y. Yang, H. Qin, M. Jiang, L. Lin, T. Fu, X. Dai, Z. Zhang, Y. Niu, H. Cao, Y. Jin, F. Zhao and X. Peng, Nano Lett., 2016, 16, 2133]

For solution processing of the 2D EL active layer, the 2D material may be dissolved in a suitable solvent. In particular embodiments, the solvent has a low vapor pressure. Use of a low vapor pressure solvent may prevent solvent evaporation during processing, and thus may mitigate issues such as so-called “coffee ring” formation and surface roughness. As used herein, the term “low vapor pressure solvent” refers to a solvent having a vapor pressure of approximately 2 kPa or lower at 20° C., such as, but not restricted to, chlorobenzene, and octane. In an alternative embodiment, other suitable solvents include, but are not restricted to: ethanol; isopropanol; toluene; and water.

In an alternative embodiment, the 2D EL active layer may be deposited by thermal processing, such as, but not restricted to: CVD; atomic layer deposition (ALD); molecular beam epitaxy (MBE); lateral heteroepitaxy; and vapor-solid growth.

An EL device according to the invention may provide the following advantages:
an all-solution processed approach may be low cost and high throughput;
the device may be built on flexible substrates, which may lead to new technologies such as roll-up displays;
solution processing may lead to high material utilization and low material consumption;
the device may offer good stability and lifetime due to the inherent stability of the inorganic 2D material; and
high efficiency blue emission from 2D emissive materials may help to overcome the limitations of blue OLEDs.

The process for preparing 2D-OLED hybrid device is illustrated in the following examples:

### Example 1: 2D-OLED Hybrid EL Device with a Conventional Device Structure

An ITO-coated glass substrate was cleaned via a wet and dry cleaning process. For the dry cleaning process the ITO-coated substrate was treated in UV ozone (in air) for 10 minutes.

PEDOT:PSS was filtered through a 0.45 μm polyvinylidine fluoride (PVDF) filter. A 50 nm PEDOT:PSS HIL was deposited via spin coating, followed by annealing in air, at 200° C., for 10 minutes.

A 12 mg/mL poly-TPD chlorobenzene solution was prepared by adding poly-TPD to chlorobenzene, under N₂, and shaking until completely dissolved. After filtering the solution through a 0.2 μm polytetrafluoroethylene (PTFE) filter, a 50 nm poly-TPD HTL was deposited via spin coating at 1,500 rpm for 1 minute, under N₂. The film was baked at 110° C., under N₂, for 1 hour.

A solution of 2D MoS₂ single-layered nanoparticles in toluene was filtered through a 0.2 μm filter, then spin coated at 2,000 rpm to deposit a 15-20 nm 2D film. The film was baked facing upwards at 110° C., on a hotplate, inside an N₂-filled glove box, for 10 minutes.

After the baking step at 110° annealing, the substrate was immediately loaded into an evaporator with a shadow mask used to define the device area, together with Alq₃, LiF and Al sources. When the vacuum reached 10⁻⁷ mbar, Alq₃ was deposited at a rate of 0.1-0.2 nm/s until a 35 nm film had been deposited. Once the source had cooled, the chamber was vented and the mask was changed to a cathode deposition mask. LiF and Al were deposited under a vacuum of 10⁻⁷ mbar, at a rate of less than 0.1 nm/s for LiF, and greater than 0.2 nm/s for Al.

The device was unloaded and encapsulated with a glass cap with a cavity depth of 0.35 mm, with desiccant getter in the bottom of the cap and UV resin on the rims, under an N₂ environment with oxygen and moisture levels less than 1 ppm. The resin was cured under a UV mercury lamp for 5 minutes. The organic and 2D layers were protected during exposure to the UV light.

### Example 2: 2D-OLED Hybrid EL Device with an Inverted Device Structure

An ITO-coated glass substrate was cleaned via a wet and dry cleaning process. For the dry cleaning process the ITO-coated substrate was treated in UV ozone (in air) for 10 minutes.

A ZnO nanoparticle solution in ethanol was subsequently spin coated at a concentration of 30 mg/mL and a spin speed of 2,000 rpm to achieve a layer thickness of 50 nm. The film was then baked in an N₂-filled glove box at a temperature of 120° C. for 20 minutes. The ZnO layer may act as both an electron injection layer and electron transport layer/hole blocking layer.

A solution of 2D MoS₂ single-layered nanoparticles in toluene was filtered through a 0.2 μm filter, then spin coated at 2,000 rpm to deposit a 15-20 nm 2D film. The film was baked facing upwards at 110° C., on a hotplate, inside an N₂-filled glove box, for 10 minutes.

After annealing, the substrate was immediately loaded into an evaporator with a shadow mask used to define the device area, together with TCTA, MoO₃ and Al sources. When the vacuum reached 10⁻⁷ mbar, TCTA was deposited at a rate of 0.1-0.2 nm/s until a 40 nm film had been deposited. Once the source had cooled, the chamber was vented and the mask was changed. MoO₃ and Al were deposited under a vacuum of 10⁻⁷ mbar, at a rate of less than 0.1 nm/s for MoO₃, and greater than 0.2 nm/s for Al.

The device was unloaded and encapsulated with a glass cap with a cavity depth of 0.35 mm, with desiccant getter in the bottom of the cap and UV resin on the rims, under an N₂ environment with oxygen and moisture levels less than 1 ppm. The resin was cured under a UV mercury lamp for 5 minutes. The organic and 2D layers were protected during exposure to the UV light.

The foregoing presents particular embodiments of a system embodying the principles of the invention. Those skilled in the art will be able to devise alternatives and variations which, even if not explicitly disclosed herein, embody those principles and are thus within the scope of the invention. Although particular embodiments of the present invention have been shown and described, they are not intended to limit what this patent covers. One skilled in the art will understand that various changes and modifications may be made without departing from the scope of the present invention as literally and equivalently covered by the following claims.

What is claimed is:

1. A 2D-OLED hybrid device comprising an inorganic two-dimensional (2D) electroluminescent (EL) active layer.

2. The device of claim 1, wherein the 2D EL active layer comprises a transition metal dichalcogenide.

3. The device of claim 1, wherein the device comprises a substrate having an adjacent anode layer.

4. The device of claim 1, wherein the device comprises a substrate having an adjacent cathode layer.

5. The device of claim 1, further comprising a buffer layer.

6. The device of claim 5, wherein the buffer layers comprises poly(methyl methacrylate).

7. The device of claim 1, further comprising a flexible substrate.

8. The device of claim 1, wherein the 2D EL active layer is substantially a monolayer.

9. A process for preparing a 2D-OLED hybrid device comprising:
a. providing a substrate coated with an anode material;
b. depositing a hole injection layer;
c. depositing a hole transport layer/electron blocking layer;
d. depositing a 2D EL active layer;
e. depositing an electron transport layer/hole blocking layer;
f. depositing an electron injection layer; and
g. depositing a cathode layer.

10. The process of claim 9, wherein the 2D EL active layer is deposited via solution processing.

11. The process of claim 9, wherein the 2D EL active layer is deposited using 2D nanoparticles.

12. The process of claim 11, wherein the 2D nanoparticles are functionalized with ligands.

13. The process of claim 12, wherein the ligands are selected from the group consisting of: short-chain ligands; and entropic ligands.

14. The process of claim 9, further comprising encapsulating the device.

15. A process for preparing a 2D-OLED hybrid device comprising:
a. providing a substrate coated with an cathode material;
b. depositing an electron injection layer/electron transport layer/hole blocking layer;
c. depositing a 2D EL active layer;
d. depositing hole transport layer/electron blocking layer;
e. depositing hole injection layer; and
f. depositing an anode layer.

16. The process of claim 15, wherein the 2D EL active layer is deposited via solution processing.

17. The process of claim 15, wherein the 2D EL active layer is deposited in the form of a solution or dispersion of 2D nanoparticles.

18. The process of claim 17, wherein the 2D nanoparticles are functionalized with ligands.

19. The process of claim 18, wherein the ligands are selected from the group consisting of: short-chain ligands; and entropic ligands.

20. The process of claim 15, further comprising encapsulating the device.
